(19) United States
(12) Patent Application Publication
(10) Pub. No.: US 2025/0155823 A1
(43) Pub. Date: May 15, 2025

(54) OPTICAL APPARATUS AND CONTROL METHOD OF OPTICAL APPARATUS

(71) Applicant: Lasertec Corporation, Yokohama (JP)

(72) Inventor: Ko GONDAIRA, Yokohama (JP)

(73) Assignee: Lasertec Corporation, Yokohama (JP)

(21) Appl. No.: 18/943,306

(22) Filed: Nov. 11, 2024

(30) Foreign Application Priority Data
Nov. 14, 2023 (JP) 2023-193375

(51) Int. Cl. G03F 7/00

(52) U.S. Cl. CPC G03F 7/702; G03F 7/70033; G03F 7/70508; G03F 7/70525; G03F 7/7055; G03F 7/7085

(57) ABSTRACT

An optical apparatus according to the present embodiment is an optical apparatus that illuminates an object with illumination light, the optical apparatus including: a first mirror unit configured to reflect a first portion of generated light including the illumination light generated from a light-emitting point; a second mirror unit configured to reflect a second portion of the generated light; an optical element configured to reflect the generated light; a first detection unit configured to detect the first portion reflected by the first mirror unit; and a second detection unit configured to detect the second portion reflected by the second mirror unit, in which the generated light includes the first portion, the second portion, and a main portion, and at least a part of the main portion reflected by the optical element is the illumination light that illuminates the object.

### INCORPORATION BY REFERENCE

This application is based upon and claims the benefit of priority from Japanese patent application No. 2023-193375, filed on Nov. 14, 2023, the disclosure of which is incorporated herein in its entirety by reference.

### BACKGROUND

The present disclosure relates to an optical apparatus and to a control method of an optical apparatus.
Patent Literature 1 discloses a technique of extracting a part from a flux of EUV (Extreme Ultra Violet) light to monitor an intensity distribution of the EUV light.
Patent Literature 2 discloses a technique of surrounding EUV light with a sensor with a hollow center to monitor a state of the EUV light.
Patent Literature 1: Japanese Patent No. 6249513
Patent Literature 2: Published Japanese Translation of PCT International Publication for Patent Application, No. 2023-515488

### SUMMARY

However, when a temporal intensity change of EUV light is observed by a monitor, it may be difficult to determine whether the change is due to a movement of a light-emitting point of the EUV light, flickering (a change in amount of light) of the light-emitting point, defocusing, or other reasons. It is desired that an emission state of EUV light be comprehensible in greater detail and that a light source of the EUV light be more finely controllable.

An object of the present disclosure, which has been made in consideration of such problems, is to provide an optical apparatus and a control method of an optical apparatus that enable an emission state of illumination light to be comprehended in greater detail and enable a light source of the illumination light to be more readily and more finely controlled.

An optical apparatus according to an aspect of the present embodiment is an optical apparatus that illuminates an object with illumination light, the optical apparatus including: a first mirror unit configured to reflect a first portion of generated light including the illumination light from a light-emitting point of the generated light; a second mirror unit configured to reflect a second portion of the generated light; an optical element configured to reflect the generated light; a first detection unit configured to detect the first portion reflected by the first mirror unit; and a second detection unit configured to detect the second portion reflected by the second mirror unit, in which the generated light includes the first portion, the second portion, and a main portion, and at least a part of the main portion reflected by the optical element is the illumination light that illuminates the object.

In the optical apparatus described above, the first mirror unit may be configured to separate the first portion from an optical path of the main portion and the second mirror unit may be configured to separate the second portion from the optical path of the main portion.

The optical apparatus described above may further include: an acquiring unit configured to acquire first output information of the first detection unit at a plurality of sampling time points and second output information of the second detection unit at the plurality of sampling time points; and a determining unit configured to determine a state of the light-emitting point based on a change in the first output information and a change in the second output information.

In the optical apparatus described above, the determining unit may be configured to determine, based on a change in the first output information of the first detection unit and a change in the second output information of the second detection unit between a predetermined sampling time point and a sampling time point after the predetermined sampling time point, a movement of the light-emitting point in an optical axis direction of the generated light and a movement of the light-emitting point in an orthogonal direction that is orthogonal to the optical axis direction.

In the optical apparatus described above, the determining unit may be configured to determine, based on a change in the first output information of the first detection unit and a change in the second output information of the second detection unit between a predetermined sampling time point and a sampling time point after the predetermined sampling time point, a change in emission intensity at the light-emitting point.

In the optical apparatus described above, the determining unit may be configured to determine that the emission intensity at the light-emitting point has changed when at least one of a change in intensity of the light-emitting point based on the first output information and a change in intensity of the light-emitting point based on the second output information is detected and, at the same time, a movement of the light-emitting point based on the first output information and a movement of the light-emitting point based on the second output information are not detected.

In the optical apparatus described above, the acquiring unit may be configured to acquire a first image by capturing the light-emitting point from the first output information, the first image having a transverse direction and a longitudinal direction that is orthogonal to the transverse direction, and acquire a second image by capturing the light-emitting point from the second output information, the second image having the transverse direction and the longitudinal direction.

In the optical apparatus described above, when the light-emitting point moves in the optical axis direction, the light-emitting point in the first image and the light-emitting point in the second image may move so as to have components in mutually opposite directions in at least one of the transverse direction and the longitudinal direction, and when the light-emitting point moves in the orthogonal direction, the light-emitting point in the first image and the light-emitting point in the second image may move so as to have components in a same direction in at least one of the transverse direction and the longitudinal direction.

In the optical apparatus described above, the determining unit may be configured to determine that the light-emitting point has moved in the optical axis direction when the light-emitting point in the first image and the light-emitting point in the second image move so as to have components in mutually opposite directions in at least one of the transverse direction and the longitudinal direction, and determine that the light-emitting point has moved in the orthogonal direction when the light-emitting point in the first image and the light-emitting point in the second image move so as to have components in a same direction in at least one of the transverse direction and the longitudinal direction.

In the optical apparatus described above, the first detection unit and the second detection unit may be arranged at optically conjugate positions with respect to the object.

In the optical apparatus described above, the generated light may further include a third portion, the optical apparatus may further include: a third mirror unit configured to reflect the third portion; and a third detection unit configured to detect the third portion reflected by the third mirror unit, and the acquiring unit may be configured to acquire third output information of the third detection unit and acquire an intensity distribution of the generated light based on the acquired third output information.

In the optical apparatus described above, the third portion may be closer to an optical axis of the main portion than the first portion and the second portion.

In the optical apparatus described above, the illumination light may be a critical illumination.

The optical apparatus described above may include a mirror configured to reflect the generated light occurring at the light-emitting point, and the first portion, the second portion, and the main portion may be the generated light reflected by the mirror.

In the optical apparatus described above, the illumination light may include a wavelength of EUV.

In the optical apparatus described above, the first detection unit and the second detection unit may be configured to detect light of wavelengths that differ from a wavelength of the illumination light.

In the optical apparatus described above, the first mirror unit and the second mirror unit may be arranged at approximately same optical path positions on an optical axis of the main portion.

In the optical apparatus described above, the first mirror unit and the second mirror unit may be arranged at opposite positions across an optical axis of the main portion.

The optical apparatus described above may further include: a fourth detection unit configured to detect the illumination light including the main portion reflected by the object; and a processing unit configured to process an image of the object based on fourth output information of the fourth detection unit.

In the optical apparatus described above, the object may include a photomask.

The optical apparatus described above may further include: a fourth detection unit configured to detect light from an observation object arranged on an optical path of the main portion; and a processing unit configured to process an image of the observation object based on fourth output information of the fourth detection unit, in which the object may include the fourth detection unit.

In the optical apparatus described above, the illumination light may include exposure light to expose a wafer, and the object may include a wafer having a region that is activated based on light from a photomask arranged on an optical path of the exposure light.

In the optical apparatus described above, the illumination light may include exposure light to expose a wafer, and the object may include a photomask configured to form a pattern on the wafer.

A control method of an optical apparatus according to an aspect of the present embodiment is a control method of an optical apparatus that illuminates an object with illumination light, the optical apparatus including: a first mirror unit that reflects a first portion of generated light including the illumination light from a light-emitting point of the generated light; a second mirror unit that reflects a second portion of the generated light; an optical element that reflects the generated light; a first detection unit that detects the first portion reflected by the first mirror unit; a second detection unit that detects the second portion reflected by the second mirror unit; and an image processing unit including an acquiring unit and a determining unit, the generated light including the first portion, the second portion, and a main portion, in which the control method of an optical apparatus includes the steps of: illuminating the object with the illumination light including at least a part of the main portion reflected by the optical element; causing the acquiring unit to acquire first output information of the first detection unit and second output information of the second detection unit at a plurality of sampling time points; and causing the determining unit to determine a state of the light-emitting point based on a change in the first output information and a change in the second output information.

According to the present disclosure, an optical apparatus and a control method of an optical apparatus that enable an emission state of illumination light to be comprehended in greater detail and enable a light source of the illumination light to be more readily and more finely controlled can be provided.

The above and other objects, features and advantages of the present disclosure will become more fully understood from the detailed description given hereinbelow and the accompanying drawings.

### BRIEF DESCRIPTION OF DRAWINGS

FIG. 1 is a plan view illustrating an optical apparatus according to a first embodiment;

FIG. 2 is a side view illustrating the optical apparatus according to the first embodiment;

FIG. 3 is a sectional view illustrating generated light and illumination light of the optical apparatus according to the first embodiment and shows a cross section along line III-III in FIG. 1;

FIG. 4 is a block diagram illustrating an image processing unit in the optical apparatus according to the first embodiment;

FIG. 5 is a diagram illustrating output information of a first detection unit and output information of a second detection unit acquired by an acquiring unit in the image processing unit in the optical apparatus according to the first embodiment;

FIG. 6 is a diagram illustrating output information of a first detection unit and output information of a second detection unit acquired by an acquiring unit in the image processing unit in the optical apparatus according to the first embodiment;

FIG. 7 is a diagram illustrating output information of a first detection unit and output information of a second detection unit acquired by an acquiring unit in the image processing unit in the optical apparatus according to the first embodiment;

FIG. 8 is a diagram illustrating output information of a first detection unit and output information of a second detection unit acquired by an acquiring unit in the image processing unit in the optical apparatus according to the first embodiment;

FIG. 9 is a diagram illustrating output information of a first detection unit and output information of a second detection unit acquired by an acquiring unit in the image processing unit in the optical apparatus according to the first embodiment;

FIG. 10 is a flowchart illustrating a control method of the optical apparatus according to the first embodiment;

FIG. 11 is a plan view illustrating an optical apparatus according to a second embodiment;

FIG. 12 is a configuration diagram illustrating an inspection apparatus according to a third embodiment;

FIG. 13 is a block diagram illustrating an image processing unit in the inspection apparatus according to the third embodiment;

FIG. 14 is a configuration diagram illustrating an inspection apparatus according to a fourth embodiment;

FIG. 15 is a configuration diagram illustrating a monitor unit in the inspection apparatus according to the fourth embodiment; and

FIG. 16 is a configuration diagram illustrating an inspection apparatus according to a fifth embodiment.

### DESCRIPTION OF EMBODIMENTS

Hereinafter, embodiments of the present disclosure will be described with reference to the drawings. The following description is intended as a description of preferred embodiments of the present disclosure and is not intended to limit the scope of the present disclosure to the following embodiments. In the following description, same reference signs denote substantially similar content.

### First Embodiment

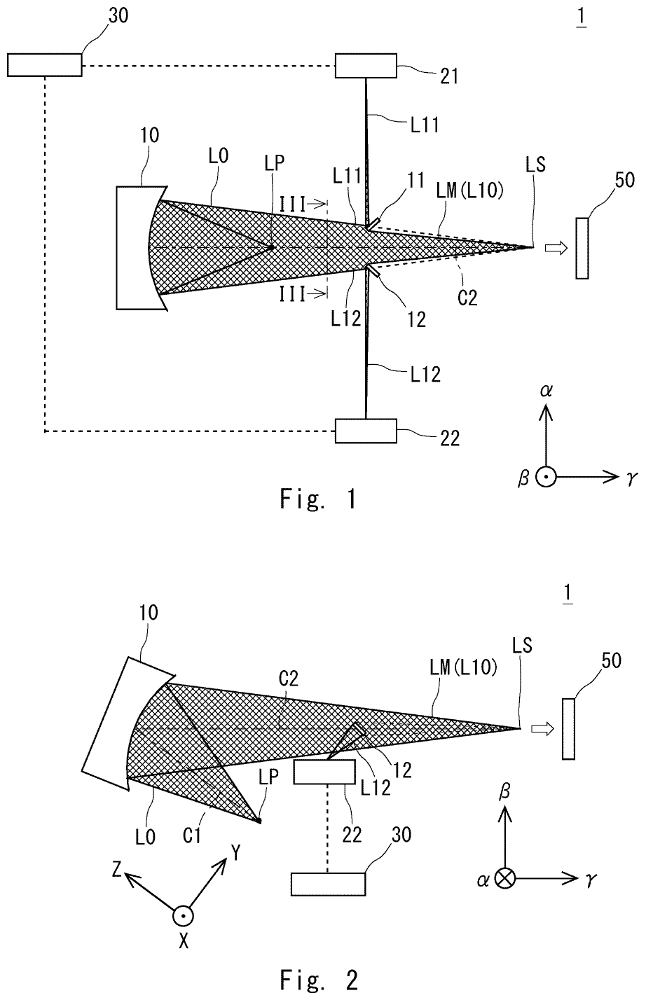

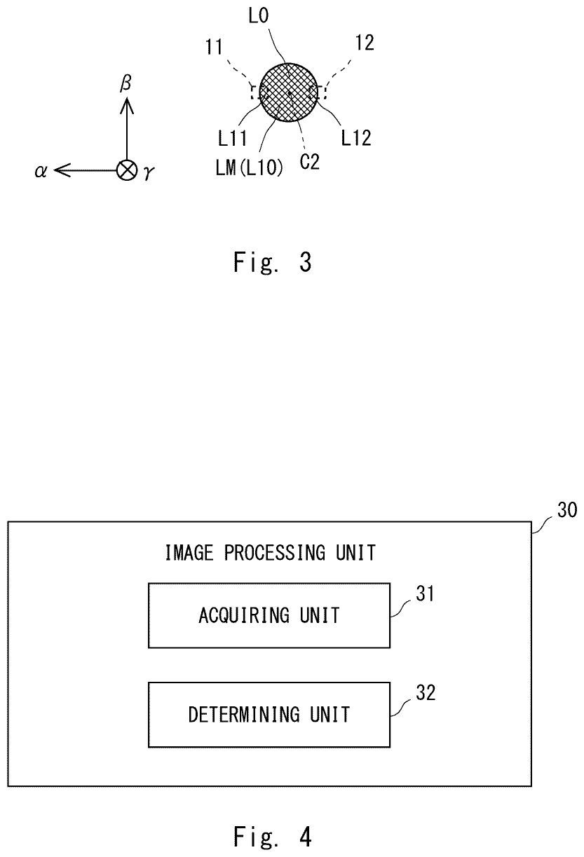

An optical apparatus according to a first embodiment will be described. FIG. 1 is a plan view illustrating an optical apparatus 1 according to the first embodiment. FIG. 2 is a side view illustrating the optical apparatus 1 according to the first embodiment. FIG. 3 is a sectional view illustrating generated light L0 and illumination light L10 of the optical apparatus 1 according to the first embodiment and shows a cross section along line III-III in FIG. 1. As shown in FIGS. 1 to 3, the optical apparatus 1 is an apparatus that illuminates an object 50 with the illumination light L10 included in the generated light L0. After passing a focusing point LS, the illumination light L10 may illuminate the object 50 via several optical members. The optical apparatus 1 may be an inspection apparatus that inspects the object 50 with the illumination light L10 or an exposure apparatus that exposes an exposure object with the illumination light L10 as exposure light and an exposure apparatus that exposes the object 50 with exposure light.

For example, the object 50 may include a photomask. Note that the object 50 may include members other than a photomask such as a semiconductor substrate. The optical apparatus 1 includes an optical element 10, a first mirror unit 11, a second mirror unit 12, a first detection unit 21, a second detection unit 22, and an image processing unit 30.

The generated light L0 including the illumination light L10 is generated by the light-emitting point LP and emitted from the light-emitting point LP. For example, the light-emitting point LP includes a bright spot of plasma generated by irradiating a target material with excitation light. In such a case, the generated light L0 and the illumination light L10 include EUV light generated from the plasma. Therefore, the generated light L0 and the illumination light L10 include a wavelength of EUV. Note that the generated light L0 and the illumination light L10 may include UV light of a wavelength other than EUV, visible light, and infrared (hereinafter, referred to as IR) light. In addition, the generated light L0 and the illumination light L10 may include a wavelength of at least any of EUV light, UV light, visible light, and IR light. The generated light L0 including the illumination light L10 is directed toward the object 50 from the light-emitting point LP. The generated light L0 emitted from the light-emitting point LP travels as a luminous flux with a beam shape. The generated light L0 spreads from the light-emitting point LP as it travels. The generated light L0 is incident to the optical element 10.

The optical element 10 reflects the generated light L0. For example, the optical element 10 includes a mirror. The optical element 10 may include a concave mirror such as a spheroidal mirror. In such a case, the optical element reflects the generated light L0 having been incident while spreading so that the reflected generated light L0 travels while being condensed. In other words, the optical element 10 reflects the generated light L0, having been incident as divergent light, as convergent light.

An XYZ orthogonal coordinate axes system and an αβγ orthogonal coordinate axes system will now be introduced for convenience of description of the optical apparatus 1. As shown in FIG. 2, let an optical axis direction that is a direction of an optical axis C1 of the generated light L0 emitted from the light-emitting point LP be a Z-axis direction and two directions orthogonal to the Z-axis direction be an X-axis direction and a Y-axis direction. A direction in an XY plane will be referred to as an orthogonal direction. In addition, as shown in FIGS. 1 to 3, let a direction of an optical axis C2 of the generated light L0 reflected by the optical element 10 be a y-axis direction and two directions orthogonal to the direction of the optical axis C2 be an a-axis direction and a β-axis direction.

For example, the light-emitting point LP is positioned in a direction having a component in the +y-axis direction and a component in the −β-axis direction of the optical element 10. The optical axis C1 of the generated light L0 traveling from the light-emitting point LP to the optical element 10 extends in a direction having a component in the −γ-axis direction and a component in the +β-axis direction.

The generated light L0 reflected by the optical element 10 travels in the ty-axis direction so as to focus at the focusing point LS. The generated light L0 includes a first portion L11, a second portion L12, and a main portion LM. For example, the first portion L11 includes a portion on a side of the ta-axis direction of the generated light L0 and the second portion L12 includes a portion on a side of the −α-axis direction of the generated light L0. Therefore, the first portion L11 and the second portion L12 are separated from each other in the a-axis direction across the optical axis C2 of the generated light L0. The first portion L11 and the second portion L12 may include EUV light, UV light, visible light, IR light, and the like.

Preferably, the first portion L11 and the second portion L12 are regions that are most separated from the optical axis C2 in the generated light L0. In addition, preferably, the first portion L11 and the second portion L12 include portions of both sides that are most separated from each other across the optical axis C2 in the generated light L0. Accordingly, sensitivity at which a change in a position of the light-emitting point LP is detected by the first detection unit 21 and the second detection unit 22 can be improved.

Note that the first portion L11 and the second portion L12 are not limited to portions separated from each other in the α-axis direction and may be separated from each other in the β-axis direction or separated from each other in an inclined direction with respect to the α-axis direction and the β-axis direction. In addition, the first portion L11 and the second portion L12 are not limited to portions separated from each other on mutually opposite sides across the optical axis C2 of the generated light L0. For example, the first portion L11 and the second portion L12 may be respectively arranged so as to be separated from each other at positions that do not sandwich the optical axis C2 of the generated light L0 such as a portion on the side of the ta-axis direction and a portion on the side of the +β-axis direction.

The first portion L11 of the generated light L0 is incident to the first mirror unit 11. In addition, the second portion L12 of the generated light L0 is incident to the second mirror unit 12. The main portion LM of the generated light L0 may include a portion other than the first portion L11 and the second portion L12. The main portion LM is focused on the focusing point LS. At least a part of the main portion LM reflected by the optical element 10 is illumination light L10 that illuminates the object 50. For example, the main portion LM may illuminate the object 50 via several optical members from the focusing point LS. The main portion LM of the illumination light L10 may illuminate the object 50 so as to focus on the object 50. In this manner, the illumination light L10 may be a critical illumination. The main portion LM has a same optical axis as the optical axis C2 of the illumination light L10.

The first mirror unit 11 reflects the first portion L11 of the generated light L0. The second mirror unit 12 reflects the second portion L12 of the generated light L0. For example, the first mirror unit 11 is arranged on the side of the +α-axis direction relative to the optical axis C2 of the generated light L0. The second mirror unit 12 is arranged on the side of the −α-axis direction relative to the optical axis C2 of the generated light L0. Therefore, the first mirror unit 11 and the second mirror unit 12 are arranged so as to be separated from each other in the α-axis direction across the optical axis C2 of the generated light L0. The first mirror unit 11 and the second mirror unit 12 are arranged at approximately same optical path positions on the optical axis C2 of the main portion LM of the generated light L0. In other words, the first mirror unit 11 and the second mirror unit 12 are positioned on a same plane that is orthogonal to the optical axis C2. In addition, the first mirror unit 11 and the second mirror unit 12 are arranged at positions that oppose each other across the optical axis C2 of the main portion LM. Alternatively, the first mirror unit 11 and the second mirror unit 12 may be integrated. The first mirror unit 11 and the second mirror unit 12 may reflect and split the first portion L11 and the second portion L12 from the main portion LM in a light pass of the main portion LM which is reflected by the optical element 10.

Note that the first mirror unit 11 and the second mirror unit 12 may be arranged at different positions on the optical axis C2. The first mirror unit 11 and the second mirror unit 12 may be arranged optically downstream of different optical elements. In other words, a plane orthogonal to the optical axis C2 on which the first mirror unit 11 is positioned and a plane orthogonal to the optical axis C2 on which the second mirror unit 12 is positioned may differ from each other. In addition, the first mirror unit 11 and the second mirror unit 12 are not limited to being arranged so as to be separated from each other in the α-axis direction and may be arranged so as to be separated from each other in the β-axis direction or arranged so as to be separated from each other in an inclined direction with respect to the α-axis direction and the β-axis direction. Furthermore, the first mirror unit 11 and the second mirror unit 12 are not limited to being arranged so as to be separated from each other on opposite sides across the optical axis C2 of the generated light L0. For example, the first mirror unit 11 and the second mirror unit 12 may be respectively arranged so as to be separated from each other at positions that do not sandwich the optical axis C2 of the generated light L0 at a position on the side of the +α-axis direction and a position on the side of the +β-axis direction.

The first mirror unit 11 reflects the first portion L11 of the generated light L0 in, for example, the ta-axis direction. The first portion L11 reflected by the first mirror unit 11 travels in the ta-axis direction. The second mirror unit 12 reflects the second portion L12 of the generated light L0 in, for example, the −α-axis direction. The second portion L12 reflected by the second mirror unit 12 travels in the −α-axis direction. In FIG. 2, directions in which the first portion L11 and the second portion L12 travel differ from those in FIG. 1. In other words, as shown in FIG. 2, the first mirror unit 11 may reflect the first portion L11 of the generated light L0 in a direction having a component in the +α-axis direction, a component in the −β-axis direction, and a component in the −γ-axis direction. The second mirror unit 12 may reflect the second portion L12 of the generated light L0 in a direction having a component in the −α-axis direction, a component in the −β-axis direction, and a component in the −γ-axis direction.

The first mirror unit 11 separates the first portion L11 from an optical path of the main portion LM. The second mirror unit 12 separates the second portion L12 from the optical path of the main portion LM.

The first detection unit 21 detects the first portion L11 reflected by the first mirror unit 11. The first detection unit 21 may be arranged at an optically conjugate position with respect to the light-emitting point LP, the focusing point LS, and the object 50. Accordingly, the first detection unit 21 can acquire a detection result of the generated light L0 as a critical illumination. The first detection unit 21 may detect EUV light, UV light, visible light, IR light, and the like included in the first portion L11. The first detection unit 21 may detect light with a wavelength that is approximately the same as the main portion LM that is the illumination light L10 or detect light with a different wavelength. The first detection unit 21 outputs a detection result of the first portion L11 to the image processing unit 30 as output information. The output information of the first detection unit 21 may be referred to as first output information. Note, the first output information is not limited to image data. The first output information may be information corresponding to two-dimensional information. Information corresponding to two-dimensional information may include information indicating the coordinate positions of pixels having intensity value higher than a predetermined intensity value and information of intensity value of such pixels.

The second detection unit 22 detects the second portion L12 reflected by the second mirror unit 12. The second detection unit 22 may be arranged at an optically conjugate position with respect to the light-emitting point LP, the focusing point LS, and the object 50. Accordingly, the second detection unit 22 can acquire a detection result of the generated light L0 as a critical illumination. The second detection unit 22 may detect EUV light, UV light, visible light, IR light, and the like included in the second portion L12. The second detection unit 22 may detect light with a wavelength that is approximately the same as the main portion LM that is the illumination light L10 or detect light with a different wavelength. The wavelength of light detected by the second detection unit 22 may be approximately the same as the wavelength of light detected by the first detection unit 21. The second detection unit 22 outputs a detection result of the second portion L12 to the image processing unit 30 as output information. The output information of the second detection unit 22 may be referred to as second output information. Note, the second output information is not limited to image data. The second output information may be information corresponding to two-dimensional information. Information corresponding to two-dimensional information may include information indicating the coordinate positions of pixels having intensity value higher than a predetermined intensity value and information of intensity value of such pixels.

The first detection unit 21 and the second detection unit 22 may be integrated. For example, the optical apparatus 1 may include a detection apparatus. The detection apparatus may include the first detection unit 21 and the second detection unit 22. An optical path of the first portion L11 from the first mirror unit 11 to the detection apparatus and an optical path of the second portion L12 from the second mirror unit 12 to the detection apparatus may be appropriately adjusted by an optical member and guided to the detection apparatus. Accordingly, the number of detection units can be reduced and cost reduction can be achieved.

The image processing unit 30 is connected to the first detection unit 21 and the second detection unit 22 by a signal line or radio in a state where information transmission is enabled. The image processing unit 30 receives output information from the first detection unit 21 and the second detection unit 22. The output information includes image data obtained by capturing the light-emitting point LP. The image processing unit 30 performs image processing of the image data received from the first detection unit 21 and the second detection unit 22 and obtained by capturing the light-emitting point LP as a two-dimensional captured image. Note, the output information that the image processing unit 30 performs image processing is not limited to image data. The image processing unit 30 may process information corresponding to two-dimensional information, for example. Note, the image processing unit 30 may be replaced with a data processing unit, comprising an acquiring unit 31 and a determining unit 32 (and a processing unit 33) explained hereafter, configured to process the output information that is information corresponding to two-dimensional information.

FIG. 4 is a block diagram illustrating the image processing unit 30 in the optical apparatus 1 according to the first embodiment. As shown in FIG. 4, the image processing unit 30 includes an acquiring unit 31 and a determining unit 32. The acquiring unit 31 and the determining unit 32 have functions as acquiring means and determining means. The acquiring unit 31 acquires first output information of the first detection unit 21 at a plurality of sampling time points and second output information of the second detection unit 22 at the plurality of sampling time points.

The determining unit 32 determines a state of the light-emitting point LP based on a change in the first output information of the first detection unit 21 at a plurality of sampling time points and a change in the second output information of the second detection unit 22 at the plurality of sampling time points. The state of the light-emitting point LP may include a state of a position of the light-emitting point LP. The state of the light-emitting point LP includes defocusing due to a movement of the light-emitting point LP in a direction of the optical axis C1, a positional displacement due to a movement of the light-emitting point LP in an orthogonal direction that is orthogonal to the optical axis C1, and flickering due to an increase or decrease of intensity of the light-emitting point LP.

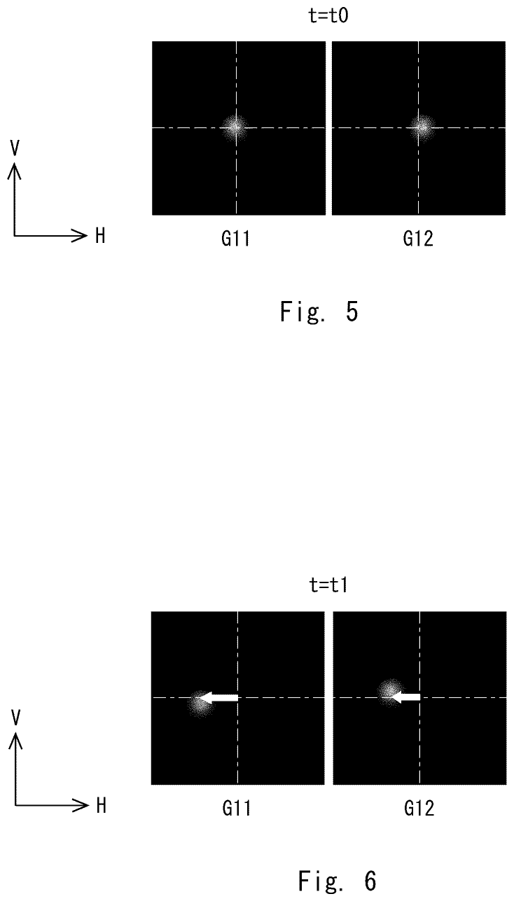

FIGS. 5 to 9 are diagrams illustrating first output information of the first detection unit 21 and second output information of the second detection unit 22 acquired by the acquiring unit 31 in the image processing unit 30 in the optical apparatus 1 according to the first embodiment. As shown in FIG. 5, the acquiring unit 31 acquires a first image G11 from the first output information. The first image G11 is an image which is obtained by capturing the light-emitting point LP and which has a transverse direction and a longitudinal direction. The longitudinal direction is a direction that intersects with the transverse direction. For example, the longitudinal direction is orthogonal to the transverse direction. In this case, the first image G11 has a rectangular shape. In this case, let the transverse direction be an H direction, a right side be a +H direction, and a left side be a −H direction. In addition, let the longitudinal direction be a V direction, an upward direction be a +V direction, and a downward direction be a −V direction.

The acquiring unit 31 acquires the first image G11 and acquires a second image G12 from the second output information. The second image G12 is an image which is obtained by capturing the light-emitting point LP and which has a transverse direction and a longitudinal direction. For example, the second image G12 has a rectangular shape.

The acquiring unit 31 acquires position information of the light-emitting point LP on the first image G11 from the first output information of the first detection unit 21. The acquiring unit 31 acquires position information of the light-emitting point LP on the second image G12 from the second output information of the second detection unit 22.

When the light-emitting point LP is positioned at a predetermined reference position at a sampling time point to, as shown in FIG. 5, the acquiring unit 31 acquires an image of the light-emitting point LP positioned at a predetermined position of the first image G11 (for example, a center of the image G11) from the first output information of the first detection unit 21 at the sampling time point t=t0. In addition, when the light-emitting point LP is positioned at the predetermined reference position at the sampling time point t=t0, the acquiring unit 31 acquires an image of the light-emitting point LP positioned at a predetermined position of the second image G12 (for example, a center of the image G12) from the second output information of the second detection unit 22 at the sampling time point to.

In this manner, in the present embodiment, the first mirror unit 11, the second mirror unit 12, the first detection unit 21, and the second detection unit 22 are arranged so that the light-emitting point LP is captured at predetermined positions of the first image G11 and the second image G12 (for example, centers of the image G11 and the image G12) when the light-emitting point LP is positioned at a predetermined reference position. For example, the positions of the first mirror unit 11, the second mirror unit 12, the first detection unit 21, and the second detection unit 22 are set in advance so that the light-emitting point LP is positioned at predetermined positions of the first image G11 and the second image G12 when the light-emitting point LP is positioned at a predetermined reference position.

As shown in FIG. 6, at a sampling time point t=t1, when the light-emitting point LP moves from the reference position in an orthogonal direction (a direction in the XY plane), the acquiring unit 31 acquires an image G11 in which the light-emitting point LP has moved in the −H direction from the center of the first image G11 from the first output information of the first detection unit 21. In addition, the acquiring unit 31 acquires an image G12 in which the light-emitting point LP has moved in the −H direction from the center of the second image G12 from the second output information of the second detection unit 22.

In this manner, in the present embodiment, the first mirror unit 11, the second mirror unit 12, the first detection unit 21, and the second detection unit 22 are arranged so that the light-emitting point LP in the first image G11 and the light-emitting point LP in the second image G12 move so as to have components in a same direction in at least any of the H direction and the V direction when the light-emitting point LP moves in the orthogonal direction (a direction in the XY plane). By adopting such an arrangement, when the light-emitting point LP moves in the orthogonal direction (a direction in the XY plane), the light-emitting point LP in the first image G11 and the light-emitting point LP in the second image G12 move so as to have components in a same direction in at least any of the H direction and the V direction. In this case, as described earlier, the orthogonal direction refers to a direction in the XY plane that is orthogonal to the optical axis C1 and includes a direction with a component of at least any of the X-axis direction and the Y-axis direction.

For example, a magnitude of an angle formed between a reflective surface of the first mirror unit 11 and the optical axis C2 is made equal to a magnitude of an angle formed between a reflective surface of the second mirror unit 12 and the optical axis C2. In addition, an arrangement is adopted so that an orientation of the reflective surface of the first mirror unit 11 with respect to the optical axis C2 and an orientation of the reflective surface of the second mirror unit 12 with respect to the optical axis C2 become symmetrical with respect to the optical axis C2. Furthermore, an arrangement is adopted so that an optical path of the first portion L11 from the first mirror unit 11 to the first detection unit 21 and an optical path of the second portion L12 from the second mirror unit 12 to the second detection unit 22 become symmetrical with respect to the optical axis C2.

By adopting such a configuration, when the light-emitting point LP moves in the orthogonal direction, the light-emitting point LP in the first image G11 and the light-emitting point LP in the second image G12 can be caused to move in a same direction in at least any of the H direction and the V direction. Note that the configuration in which the light-emitting points LP in the first image G11 and the second image G12 are caused to move as described above when the light-emitting point LP moves in the orthogonal direction is not limited to the configuration described above and angles of reflective surfaces and the number of optical members may be appropriately changed.

The determining unit 32 determines a movement of the light-emitting point LP in the direction of the optical axis C1 and a movement of the light-emitting point LP in the orthogonal direction based on a change in the first output information of the first detection unit 21 and a change in the second output information of the second detection unit 22 between a predetermined sampling time point t=t0 and a sampling time point t=t1. In this case, the sampling time point t=t1 is a time point after the predetermined sampling time point t=t0. The direction of the optical axis C1 is a direction of the optical axis C1 of the generated light L0 emitted from the light-emitting point LP at the predetermined sampling time point t=t0.

Specifically, the determining unit 32 determines that the light-emitting point LP has moved in the orthogonal direction when the light-emitting point LP in the first image G11 and the light-emitting point LP in the second image G12 move so as to have components in a same direction in at least any of the H direction and the V direction.

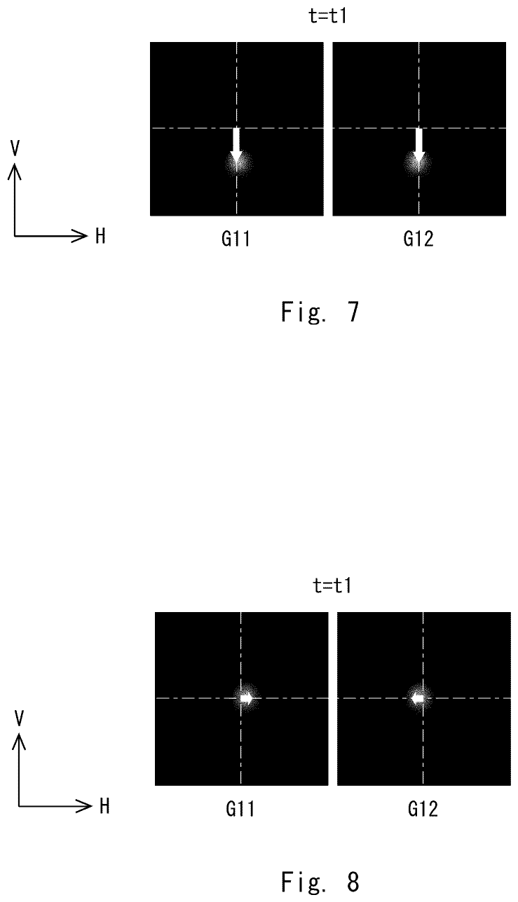

As shown in FIG. 7, at a sampling time point t=t1, when the light-emitting point LP moves from the reference position in an orthogonal direction that differs from FIG. 6, the acquiring unit 31 acquires an image G11 in which the light-emitting point LP has moved in the −V direction from the center of the first image G11 from the first output information of the first detection unit 21. The acquiring unit 31 acquires an image G12 in which the light-emitting point LP has moved in the −V direction from the center of the second image G12 from the second output information of the second detection unit 22.

As described above, the first mirror unit 11, the second mirror unit 12, the first detection unit 21, and the second detection unit 22 are arranged so that the light-emitting point LP in the first image G11 and the light-emitting point LP in the second image G12 move, as an example, so as to have components in a same direction in at least any of the H direction and the V direction when the light-emitting point LP moves in the orthogonal direction. Accordingly, when the light-emitting point LP moves in the orthogonal direction, the light-emitting point LP in the first image G11 and the light-emitting point LP in the second image G12 move so as to have components in a same direction in at least any of the H direction and the V direction as shown in FIG. 7. However, in FIG. 7, the orthogonal direction in which the light-emitting point LP moves differs from FIG. 6.

The determining unit 32 determines that the light-emitting point LP has moved in the orthogonal direction that differs from FIG. 6 when the light-emitting point LP in the first image G11 and the light-emitting point LP in the second image G12 move so as to have same components in a direction that differs from FIG. 6 in at least any of the H direction and the V direction.

For example, movements and amounts of movement in the X-axis direction and the Y-axis direction of the light-emitting point LP in an orthogonal direction may be associated in advance with movements and amounts of movement in the H direction and the V direction of the light-emitting points LP on the image G11 and on the image G12. Accordingly, the determining unit 32 can determine an actual direction of movement and amount of the movement of the light-emitting point LP from the movements and amounts of movement of the light-emitting points LP on the image G11 and on the image G12.

As shown in FIG. 8, at a sampling time point t=t1, when the light-emitting point LP moves from the reference position in a direction of the optical axis C1 (the Z-axis direction), the acquiring unit 31 acquires the image G11 in which the light-emitting point LP has moved in the +H direction from the center of the first image G11 from the first output information of the first detection unit 21. In addition, the acquiring unit 31 acquires an image in which the light-emitting point LP has moved in the −H direction from the center of the second image G12 from the second output information of the second detection unit 22.

In this manner, in the present embodiment, the first mirror unit 11, the second mirror unit 12, the first detection unit 21, and the second detection unit 22 are arranged so that the light-emitting point LP in the first image G11 and the light-emitting point LP in the second image G12 move, as an example, so as to have components in mutually opposite directions in at least any of the H direction and the V direction when the light-emitting point LP moves in the direction of the optical axis C1. By adopting such an arrangement, when the light-emitting point LP moves in the direction of the optical axis C1, the light-emitting point LP in the first image G11 and the light-emitting point LP in the second image G12 move so as to have components in mutually opposite directions in at least any of the H direction and the V direction.

The determining unit 32 determines that the light-emitting point LP has moved in the direction of the optical axis C1 when the light-emitting point LP in the first image G11 and the light-emitting point LP in the second image G12 move so as to have components in mutually opposite directions in at least any of the H direction and the V direction.

For example, the first mirror unit 11 and the second mirror unit 12 are arranged at positions that are symmetrical with respect to the optical axis C2. In addition, the first detection unit 21 and the second detection unit 22 are arranged so that a detecting surface of the first detection unit 21 and a detecting surface of the second detection unit 22 oppose each other. In this case, when the light-emitting point LP moves along the optical axis C1, defocusing occurs at the focusing point LS.

As a result, the focusing point LS moves in a +γ-axis direction or a −γ-axis direction. Therefore, a focusing point on the detecting surface in the first detection unit 21 moves in the +γ-axis direction or the −γ-axis direction on the detecting surface. The focusing point on the detecting surface in the second detection unit 22 moves in the +γ-axis direction or the −γ-axis direction on the detecting surface. In this manner, when the light-emitting point LP moves in the direction of the optical axis C1, the light-emitting point LP in the first image G11 and the light-emitting point LP in the second image G12 move so as to have components in mutually opposite directions in at least any of the H direction and the V direction. Note that the configuration in which the light-emitting points LP in the first image G11 and the second image G12 are caused to move as described above when the light-emitting point LP moves in the direction of the optical axis C1 is not limited to the configuration described above and angles of reflective surfaces and the number of optical members may be appropriately changed.

For example, an amount of movement of the light-emitting point LP in the direction of the optical axis C1 and amounts of movement in the H direction and the V direction of the light-emitting points LP on the image G11 and on the image G12 may be associated with each other in advance. Accordingly, the determining unit 32 can determine an actual amount of the movement of the light-emitting point LP in the direction of the optical axis C1 from the amounts of movement in opposite directions of the light-emitting points LP on the image G11 and on the image G12.

In addition, the determining unit 32 may calculate an average value of positions of the light-emitting point LP in the first image G11 and the light-emitting point LP in the second image G12 when the light-emitting point LP in the first image G11 and the light-emitting point LP in the second image G12 move so as to have components in mutually opposite directions in at least any of the H direction and the V direction. Furthermore, the average value of the positions of the light-emitting point LP and an actual positional displacement of the light-emitting point LP in the direction of the optical axis C1 may be associated with each other in advance. Accordingly, when the light-emitting point LP in the first image G11 and the light-emitting point LP in the second image G12 move so as to have components in mutually opposite directions, the determining unit 32 can determine an actual positional displacement in the direction of the optical axis C1, a movement in the orthogonal direction, and the like of the light-emitting point LP from the calculated average value.

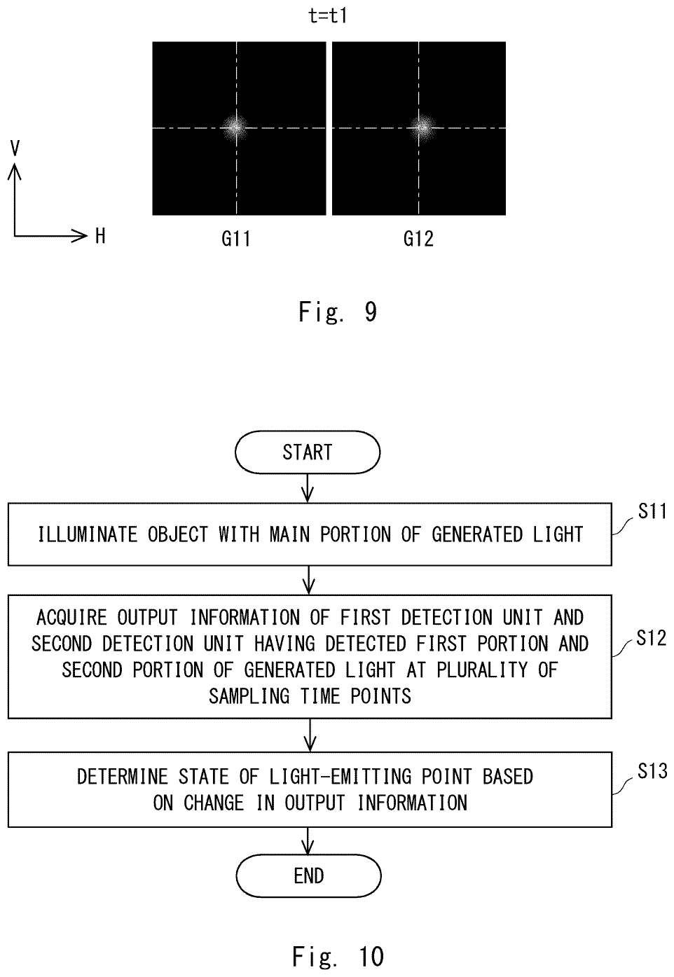

As shown in FIG. 9, at a sampling time point t=t1, when the light-emitting point LP does not move from the reference position, the acquiring unit 31 acquires the image G11 in which the light-emitting point LP does not move in any direction from the center of the first image G11 from the first output information of the first detection unit 21. In addition, the acquiring unit 31 acquires an image in which the light-emitting point LP does not move in any direction from the center of the second image G12 from the second output information of the second detection unit 22.

In this manner, in the present embodiment, the first mirror unit 11, the second mirror unit 12, the first detection unit 21, and the second detection unit 22 are arranged so that the light-emitting point LP in the first image G11 and the light-emitting point LP in the second image G12 do not move in either the H direction or the V direction when the light-emitting point LP does not move in either the direction of the optical axis C1 or the orthogonal direction. By adopting such an arrangement, when the light-emitting point LP does not move in either the direction of the optical axis C1 or the orthogonal direction, the light-emitting point LP in the first image G11 and the light-emitting point LP in the second image G12 do not move in either the H direction or the V direction.

The determining unit 32 determines that the light-emitting point LP has not moved in either the direction of the optical axis C1 or the orthogonal direction when the light-emitting point LP in the first image G11 and the light-emitting point LP in the second image G12 do not move in either the H direction or the V direction.

For example, when an intensity of the light-emitting point LP in the first image G11 or an intensity of the light-emitting point LP in the second image G12 has changed from the intensity at the sampling time point t=t0, a movement of the light-emitting point LP in the direction of the optical axis C1 (so-called defocusing), a change in emission intensity at the light-emitting point LP, or both of these factors are conceivable as reasons for such a change in intensity. As described earlier, the determining unit 32 can determine a movement of the light-emitting point LP in the direction of the optical axis C1. Therefore, as shown in FIG. 9, when the intensity of the light-emitting point LP in the first image G11 or the intensity of the light-emitting point LP in the second image G12 has changed from the intensity at the sampling time point t=t0 and the determining unit 32 does not detect a movement of the light-emitting point LP (more specifically, a movement in a mode associated with a determination of a movement of the light-emitting point LP in the direction of the optical axis C1), a determination can be made that a change in the emission intensity at the light-emitting point LP is dominant as the reason for the change in intensity of the illumination light L10. Conceivable causes of a decline in emission intensity among changes in emission intensity at the light-emitting point LP include a temporary shortage of target material and a temporary decline in output of an excitation laser. Therefore, the determining unit 32 may continue to exercise control for addressing such issues. In addition, conversely, when the intensity of the light-emitting point LP in the first image G11 or the intensity of the light-emitting point LP in the second image G12 has changed (for example, declined) from the intensity at the sampling time point t=t0 and the determining unit 32 detects a movement of the light-emitting point LP (more specifically, a movement in a mode associated with a determination of a movement of the light-emitting point LP in the direction of the optical axis C1), a determination can be made that an occurrence of a movement of the light-emitting point LP in the direction of the optical axis C1 (so-called defocusing) is the reason for the change (for example, a decline) in intensity of the illumination light L10.

Next, a control method of the optical apparatus 1 will be described. FIG. is a flowchart illustrating a control method of the optical apparatus according to the first embodiment. As shown in step S11 in FIG. 10, the object 50 is illuminated by at least a part of the main portion LM in the generated light L0 reflected by the optical element 10.

Next, as shown in step S12, the acquiring unit 31 is caused to acquire the first output information of the first detection unit 21 having detected the first portion L11 of the generated light L0 and the second output information of the second detection unit 22 having detected the second portion L12 of the generated light L0 at a plurality of sampling time points. The first mirror unit 11 reflects the first portion L11 of the generated light L0 and separates the first portion L11 from the optical path of the main portion LM. The second mirror unit 12 reflects the second portion L12 of the generated light L0 and separates the second portion L12 from the optical path of the main portion LM. In step S12, the acquiring unit 31 is caused to acquire the first image G11 obtained by capturing the light-emitting point LP from the first output information. In addition, the acquiring unit 31 is caused to acquire the second image G12 obtained by capturing the light-emitting point LP from the second output information.

Next, as shown in step S13, the determining unit 32 is caused to determine a state of the light-emitting point LP based on a change in the first output information and a change in the second output information. For example, the determining unit 32 is caused to determine a movement of the light-emitting point LP in the direction of the optical axis C1, a movement of the light-emitting point LP in the orthogonal direction, and an intensity change due to flickering of the light-emitting point LP based on a change in the first output information and a change in the second output information between a predetermined sampling time point t=t0 and a sampling time point t=t1.

Specifically, the determining unit 32 determines that the light-emitting point LP has moved in the direction of the optical axis C1 when the light-emitting point LP in the first image G11 and the light-emitting point LP in the second image G12 move so as to have components in mutually opposite directions in at least any of the transverse direction and the longitudinal direction. On the other hand, the determining unit 32 determines that the light-emitting point LP has moved in the orthogonal direction when the light-emitting point LP in the first image G11 and the light-emitting point LP in the second image G12 move so as to have components in a same direction in at least any of the transverse direction and the longitudinal direction. In addition, when the intensity of the illumination light L10 changes, the determining unit 32 determines that a change in emission intensity due to flickering of the light-emitting point LP has occurred when the light-emitting point LP in the first image G11 and the light-emitting point LP in the second image G12 do not move in either the transverse direction or the longitudinal direction. In this manner, the optical apparatus 1 can be controlled by determining a state of the light-emitting point LP.

Next, an advantageous effect of the present embodiment will be described. The optical apparatus 1 according to the present embodiment includes the first detection unit 21 and the second detection unit 22 that detect the first portion L11 and the second portion L12 of the generated light L0. Since a state of the light-emitting point LP is determined by detecting light of at least two locations in the generated light L0 in this manner, the state of the light-emitting point LP can be comprehended with greater detail and a light source of the illumination light L10 can be more readily and more finely controlled.

The determining unit 32 determines a movement of the light-emitting point LP in the direction of the optical axis C1 and a movement of the light-emitting point LP in the orthogonal direction based on movements of the light-emitting point LP on the image G11 and the image G12 acquired by the acquiring unit 31. Accordingly, a position of the light-emitting point LP can be monitored three-dimensionally. Therefore, the position of the light-emitting point LP can be comprehended with greater detail.

For example, when a decline in brightness of the light-emitting point LP, a decline in intensity of the illumination light L10, or the like is detected, it may be necessary to determine whether such declines are due to defocusing caused by a movement of the light-emitting point LP in the direction of the optical axis C1, a positional displacement of the light-emitting point LP in the orthogonal direction, or flickering due to an increase or decrease in output at the light-emitting point LP. The determining unit 32 according to the present embodiment is capable of determining a decline in intensity or the like due to a movement of the light-emitting point LP in the direction of the optical axis C1, a decline in intensity or the like due to a movement in the orthogonal direction, and a decline in intensity or the like due to flickering of the light-emitting point LP based on a movement of the positions of the light-emitting points LP on the image G11 and on the image G12. Therefore, reasons for a decline in intensity or the like of the light-emitting point LP can be distinguished.

The first detection unit 21 and the second detection unit 22 are arranged at optically conjugate positions with respect to the object 50 and the illumination light L10 is a critical illumination. Therefore, the state of the illumination light L10 can be comprehended with greater detail.

### Second Embodiment

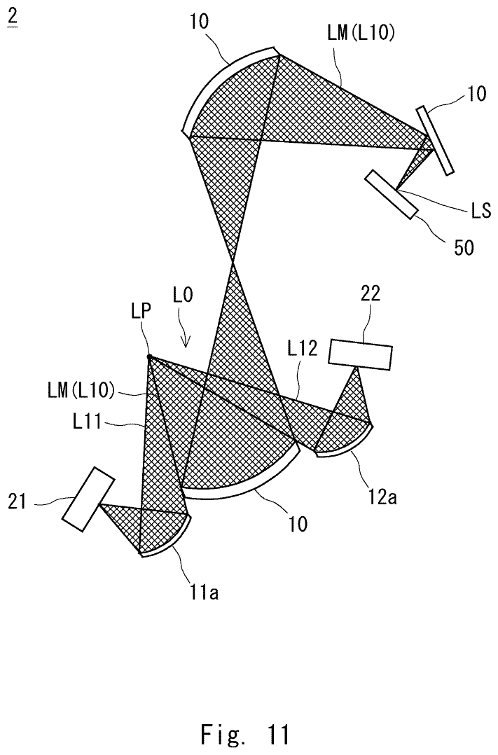

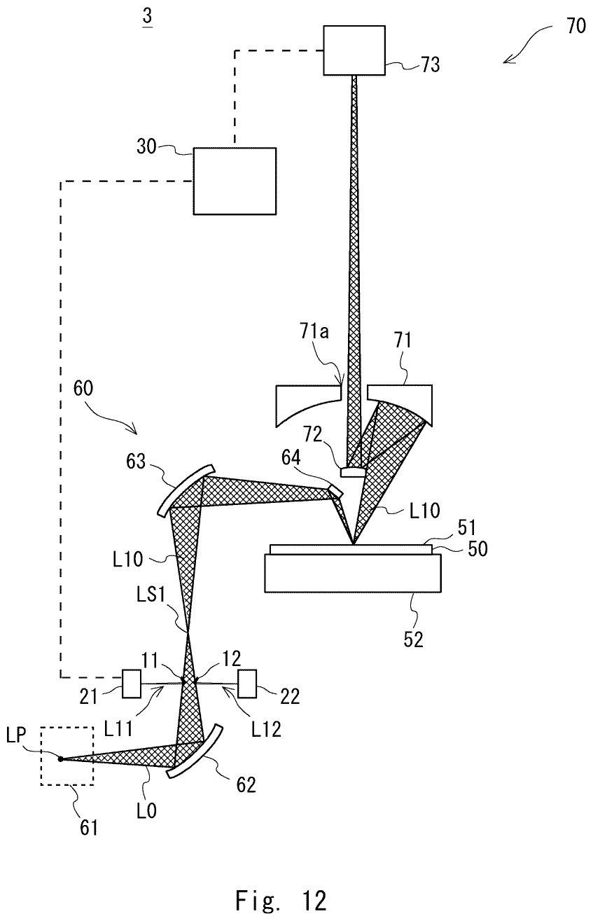

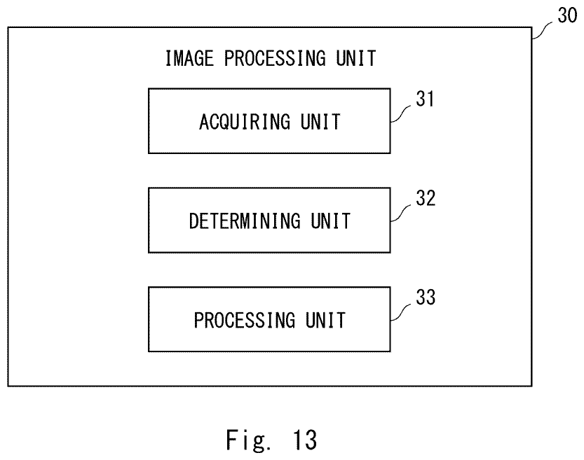

Next, an optical apparatus 2 according to a second embodiment will be described. FIG. 11 is a plan view illustrating the optical apparatus 2 according to the second embodiment. As shown in FIG. 11, even in the optical apparatus 2 according to the present embodiment, the generated light L0 includes the first portion L11, the second portion L12, and the main portion LM. The first mirror unit 11 reflects the first portion L11 of the generated light L0 from the light-emitting point LP. The second mirror unit 12 reflects the second portion L12 of the generated light L0 from the light-emitting point LP. The optical element 10 reflects the main portion LM of the generated light L0. At least a part of the main portion LM reflected by the optical element 10 illuminates the object 50. Even in the present embodiment, the optical apparatus 2 can be controlled by determining a state of the light-emitting point LP. Note that the point adopted as the light-emitting point LP is not limited to the above and may be a point where the generated light L0 is focused by an optical member such as a focusing point LS1 (refer to FIG. 12) at which the generated light L0 is focused by a spheroidal mirror. The first mirror unit 11 may reflect the generated light L0 from the light-emitting point LP and the second mirror unit 12 may reflect and split the second portion L12 from the main portion LM in a light pass of the main portion LM which is reflected by the optical element 10.

The present embodiment makes it possible to appropriately change the arrangement of the optical element 10, the first mirror unit 11, and the second mirror unit 12. Therefore, a degree of freedom of arrangement of the respective members of the optical apparatus 2 can be increased. Other configurations and advantageous effects are included in the description of the first embodiment.

### Third Embodiment

Next, an optical apparatus according to a third embodiment will be described. In the present embodiment, an inspection apparatus will be described as an example of an optical apparatus. In the inspection apparatus according to the present embodiment, for example, the object 50 may include a photomask.

FIG. 12 is a configuration diagram illustrating an inspection apparatus 3 according to the third embodiment. The inspection apparatus 3 includes an illuminating optical system 60 and an image capturing optical system 70 in addition to the configurations of the optical apparatuses 1 and 2 described earlier. The illuminating optical system 60 illuminates the object 50 using the illumination light L10. For example, the illuminating optical system 60 includes a light source 61, a spheroidal mirror 62, a spheroidal mirror 63, and a drop-in mirror 64. The image capturing optical system 70 captures an image of the object 50 illuminated by the illumination light L10. For example, the image capturing optical system 70 includes a holed concave mirror 71, a convex mirror 72, and a main detection unit 73. The holed concave mirror 71 and the convex mirror 72 constitute a Schwarzschild magnifying optical system. Note that the illuminating optical system 60 and the image capturing optical system 70 may further include an optical member in addition to the configurations described above or any of the optical members described above may be omitted.

For example, the object 50 is arranged on a stage 52. The inspection apparatus 3 is an apparatus that inspects a defect, a stain, or the like of the object 50. For example, the object 50 is an EUV mask that accommodates EUV light. Note that the object 50 is not limited to an EUV mask and may be a photomask that accommodates the illumination light L10 with another wavelength. In addition, the object 50 is not limited to a photomask and may be a semiconductor substrate or the like.

The light source 61 generates the generated light L0. For example, the generated light L0 is generated from the light-emitting point LP described earlier. For example, the generated light L0 includes EUV light of a same wavelength of 13.5 nm as an exposure wavelength of the EUV mask being the object 50. The light source 61 may include light of another wavelength as the generated light L0. The generated light L0 having been generated from the light source 61 is reflected by the spheroidal mirror 62. The generated light L0 reflected by the spheroidal mirror 62 travels while being condensed and is focused on a focusing point LS1. The focusing point LS1 is arranged at a position conjugate to an upper surface 51 of the object 50.

The first mirror unit 11 reflects the first portion L11 of the generated light L0 between the spheroidal mirror 62 and the focusing point LS1. Accordingly, the first detection unit 21 detects the first portion L11 reflected by the first mirror unit 11. The second mirror unit 12 reflects the second portion L12 of the generated light L0 between the spheroidal mirror 62 and the focusing point LS1. Accordingly, the second detection unit 22 detects the second portion L12 reflected by the second mirror unit 12.

Note that arrangement positions of the first mirror unit 11 and the second mirror unit 12 are not limited to being between the spheroidal mirror 62 and the focusing point LS1. The arrangement positions of the first mirror unit 11 and the second mirror unit 12 need only be between the light-emitting point LP and the object 50 and may be, for example, between the spheroidal mirror 63 and the drop-in mirror 64.

After passing the focusing point LS1, the illumination light L10 including the main portion LM travels while spreading and is incident to a reflective mirror such as the spheroidal mirror 63. The illumination light L10 incident to the spheroidal mirror 63 is reflected by the spheroidal mirror 63, travels while being condensed, and is incident to the drop-in mirror 64. In other words, the spheroidal mirror 63 causes the illumination light L10 to be incident to the drop-in mirror 64 as convergent light. The drop-in mirror 64 is arranged above the object 50. The illumination light L10 incident to and reflected by the drop-in mirror 64 is incident to the object 50. In other words, the drop-in mirror 64 causes the illumination light L10 to be incident to the object 50.

The spheroidal mirror 63 focuses the illumination light L10 on the object 50. The illuminating optical system 60 is installed such that an image of the light-emitting point LP is formed on the upper surface 51 of the object 50 when the illumination light L10 illuminates the object 50. Accordingly, the illuminating optical system 60 constitutes a critical illumination. In this manner, the illuminating optical system 60 illuminates the object 50 using the critical illumination due to the illumination light L10 generated by the light source 61. The illumination light L10 including the main portion LM is incident to the object 50 from a direction that is inclined with respect to a normal direction of a stage surface of the stage 52. In other words, the illumination light L10 is obliquely incident and illuminates the object 50.

The stage 52 is a three-dimensionally driven stage. Moving the stage 52 in a direction parallel to the stage surface enables a desired region of the object 50 to be illuminated. Furthermore, moving the stage 52 in the normal direction of the stage surface enables focus to be adjusted. In addition, the stage 52 may be rotated with three axes such as the X axis, the Y axis, and the Z axis as rotational axes. Note that the illuminating optical system 60 and the image capturing optical system 70 may be moved and rotated instead of moving and rotating the stage 52.

The illumination light L10 from the light source 61 illuminates an inspection region of the object 50. The illumination light L10 incident in a direction inclined with respect to the normal direction of the stage surface and reflected by the object 50 is incident to the holed concave mirror 71. A hole 71a is provided at a center of the holed concave mirror 71.

The illumination light L10 reflected by the holed concave mirror 71 is incident to the convex mirror 72. The convex mirror 72 reflects the illumination light L10 incident from the holed concave mirror 71 toward the hole 71a of the holed concave mirror 71. The illumination light L10 having passed through the hole 71a is detected by the main detection unit 73. The main detection unit 73 may be a detector including a TDI (Time Delay Integration) sensor. The main detection unit 73 detects the illumination light L10 including the main portion LM reflected by the object 50. The main detection unit 73 may include a plurality of image capturing elements arranged in a line-shape in one direction. Image data in a line-shape captured by the plurality of image capturing elements arranged in a line-shape is referred to as one-dimensional image data or one frame. The main detection unit 73 acquires a plurality of pieces of one-dimensional image data by performing a scan in a direction orthogonal to the one direction. For example, the image capturing element is a CCD (Charge Coupled Device). Note that the image capturing element is not limited to a CCD.

As described above, the image capturing optical system 70 focuses the illumination light L10 reflected by the illuminated object 50, detects the focused illumination light L10 with the main detection unit 73, and acquires image data of the object 50.

The illumination light L10 reflected by the object 50 includes information such as a defect or the like of the object 50. Regular reflected light of the illumination light L10 incident to the object 50 in a direction inclined with respect to the stage surface is detected by the image capturing optical system 70. When a defect is present in the object 50, the defect is observed as a dark image. Such an observation method is referred to as bright-field observation. Output information of the object 50 acquired by the main detection unit 73 is outputted to the image processing unit 30.

The image processing unit 30 is connected to the image capturing optical system 70 by a signal line or radio in a state where information transmission is enabled. The image processing unit 30 receives image data of the object 50 from the main detection unit 73 in the image capturing optical system 70. The image processing unit 30 performs image processing of the image data of the object 50 received from the main detection unit 73 as a two-dimensional captured image. The image processing unit 30 inspects the object 50 using the captured image subjected to image processing.

FIG. 13 is a block diagram illustrating the image processing unit 30 in the inspection apparatus 3 according to the third embodiment. As shown in FIG. 13, the image processing unit 30 may further include a processing unit 33 in addition to the acquiring unit 31 and the determining unit 32. The acquiring unit 31 acquires output information from the main detection unit 73. For example, the output information includes one-dimensional image data of the object 50. The acquiring unit 31 may acquire a captured image of the object 50 from the output information of the main detection unit 73. The processing unit 33 processes the image of the object 50. The processing unit 33 inspects the object 50 based on the processed image.

The inspection apparatus 3 according to the present embodiment includes the main detection unit 73 that detects the illumination light L10 reflected by the object 50 and the processing unit 33 that processes an image of the object 50 based on output information of the main detection unit 73. States of the light-emitting point LP and the illumination light L10 have been determined by the determining unit 32. Accordingly, the processing unit 33 can process the image of the object 50 based on a determination result by the determining unit 32 and increase accuracy of an inspection of the object 50. Other configurations and advantageous effects are included in the descriptions of the first and second embodiments.

### Fourth Embodiment

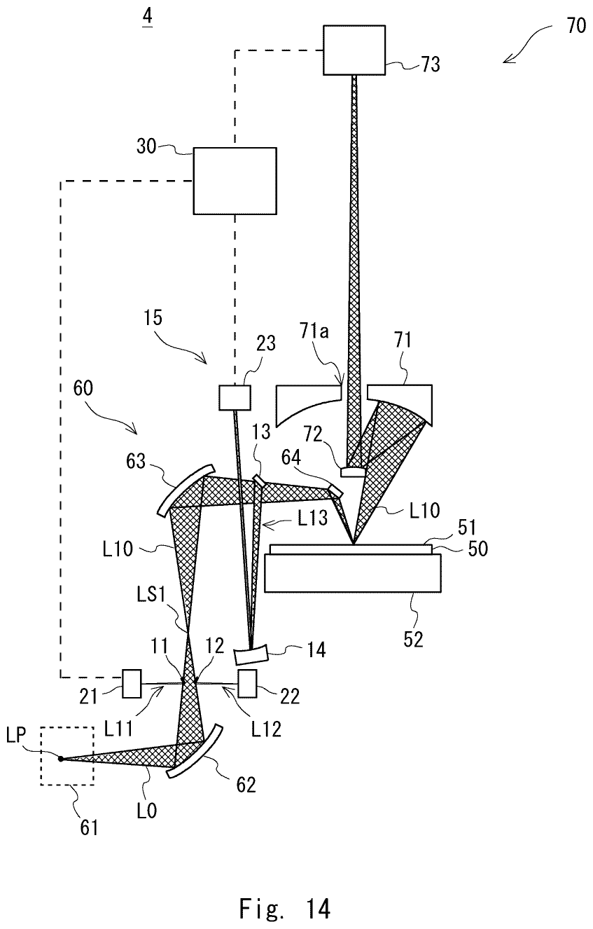

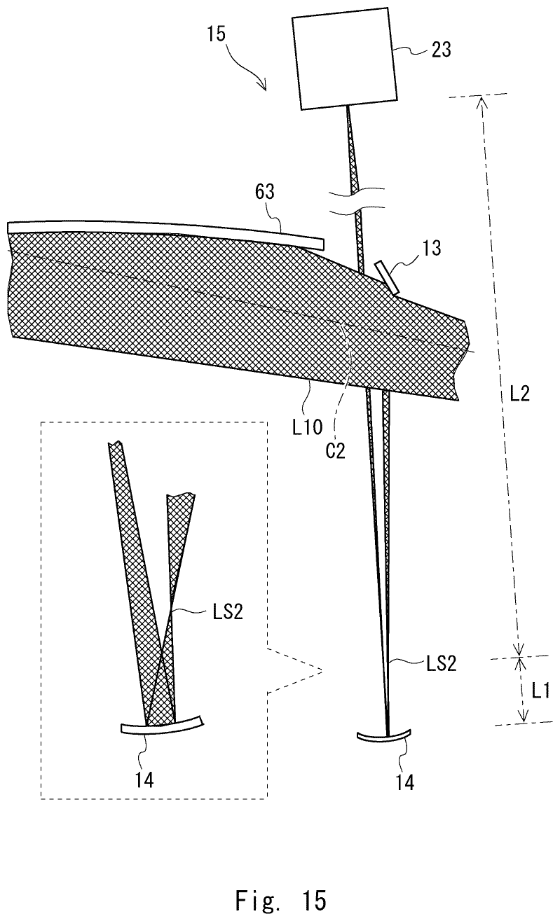

Next, an optical apparatus according to a fourth embodiment will be described. The optical apparatus according to the present embodiment is an inspection apparatus and includes a monitor unit that monitors the generated light L0 including the illumination light L10. FIG. 14 is a configuration diagram illustrating an inspection apparatus 4 according to the fourth embodiment. As shown in FIG. 14, the inspection apparatus 4 further includes a monitor unit 15. The monitor unit 15 further includes a third mirror unit 13, a concave mirror 14, and a third detection unit 23. The generated light L0 further includes a third portion L13 in addition to the first portion L11, the second portion L12, and the main portion LM.

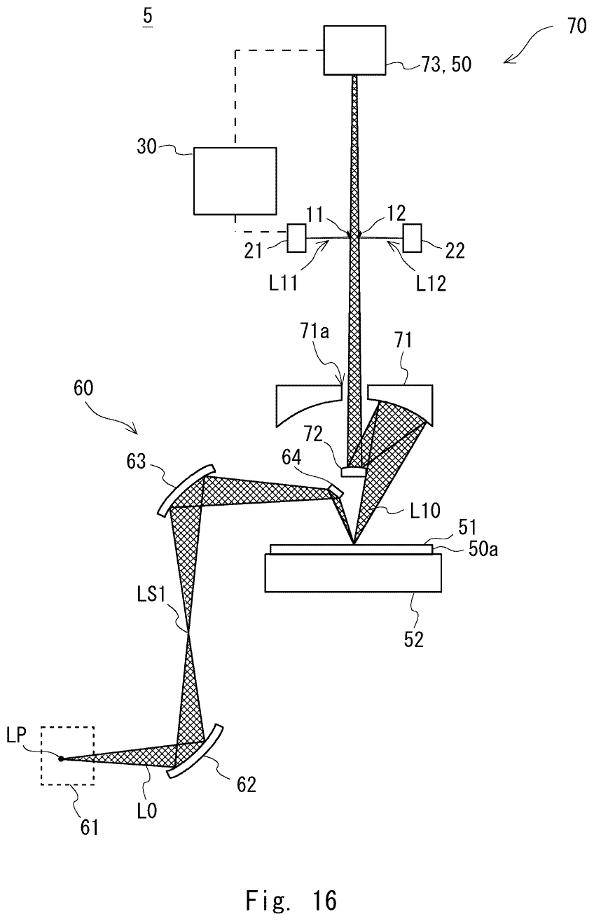

FIG. 15 is a configuration diagram illustrating the monitor unit 15 in the inspection apparatus 4 according to the fourth embodiment. FIG. 15 also shows an enlarged view of a vicinity of the concave mirror 14. As shown in FIGS. 14 and 15, the third mirror unit 13 of the monitor unit 15 is arranged between the spheroidal mirror 63 and the drop-in mirror 64 and extracts the third portion L13 of the generated light L0 between the spheroidal mirror 63 and the drop-in mirror 64. The third mirror unit 13 reflects the third portion L13 so as to chop a small part of a beam of the generated light L0.

Note that an arrangement position of the third mirror unit 13 is not limited to being between the spheroidal mirror 63 and the drop-in mirror 64. The arrangement position of the third mirror unit 13 need only be between the light-emitting point LP and the object 50 and may be, for example, between the spheroidal mirror 62 and the focusing point LS.

In a cross-sectional area of a cross section orthogonal to the optical axis C2 of the generated light L0 at a position where the third mirror unit 13 is arranged, a cross-sectional area of the third portion L13 that is reflected by the third mirror unit 13 is smaller than a cross-sectional area of the main portion LM.

For example, if a cross-sectional area of a cross section orthogonal to the optical axis C2 of the generated light L0 at the position where the third mirror unit 13 is arranged is 100, the cross-sectional area of the third portion L13 is around 1. In the generated light L0 extracted from the light source 61, a take-off angle in a direction orthogonal to the optical axis C2 is, for example, +7°. Light used as the illumination light L10 with respect to the EUV mask of the object 50 is, for example, within a range of +6°. An amount of the illumination light L10 on the EUV mask hardly decreases even when the beam of the generated light L0 is slightly extracted to be used by the monitor unit 15. Therefore, a decline in inspection accuracy of the object 50 can be suppressed.

For example, the third mirror unit 13 is arranged at a position close to a pupil in the illuminating optical system 60. Extracting the generated light L0 using the third mirror unit 13 at a position close to the pupil in the illuminating optical system 60 enables a good correlation to be made between image data acquired by the main detection unit 73 and image data acquired by the third detection unit 23. Even if a numerical aperture (NA) with respect to the main detection unit 73 and an NA with respect to the third detection unit 23 differ from each other and point spread functions (PSFs) also differ from each other, since a plasma size is significantly larger than a PSF size, the present embodiment is not affected by the difference in NAs.

The third mirror unit 13 reflects the third portion L13 in the generated light L0. Accordingly, the third mirror unit 13 separates the third portion L13 from the optical path of the main portion LM. Preferably, the third mirror unit 13 is arranged at a position that is closer to the optical axis C2 of the main portion LM than the first mirror unit 11 and the second mirror unit 12. In other words, the third portion L13 is closer to the optical axis C2 of the main portion LM than the first portion L11 and the second portion L12. Accordingly, the first portion L11 and the second portion L12 to be reflected by the first mirror unit 11 and the second mirror unit 12 can be secured.

The third portion L13 reflected by the third mirror unit 13 travels while being condensed and is focused on a focusing point LS2. Subsequently, the third portion L13 is incident to the concave mirror 14 while spreading.

The concave mirror 14 and a plurality of mirrors (not illustrated) enlarge the third portion L13 of the generated light L0 extracted by the third mirror unit 13. Let a distance between the focusing point LS2 and the concave mirror 14 be a distance L1 and a distance between the focusing point LS2 and the third detection unit 23 be a distance L2. Image data acquired by the third detection unit 23 can also be magnified to a high magnification. However, in order to obtain a high magnification (up to 500 times), the distance L2 is made extremely large. For example, when the distance L1 is set to up to 5 mm, a magnification of 500 times is achieved by setting the distance L2 up to 2500 mm. For example, a magnification of 500 times can be achieved using a plurality of mirrors.

In the present embodiment, a magnification in image data of an intensity distribution of the generated light L0 acquired by the monitor unit 15 is set to a same magnification as a magnification of image data of the object 50 acquired by the image capturing optical system 70. Note that the magnification in image data of the intensity distribution acquired by the monitor unit 15 may be set lower than the magnification of image data of the object 50 acquired by the image capturing optical system 70. A solid angle required for extraction is a square of a ratio of magnifications. For example, when the magnification of the main detection unit 73 is 20 times and the magnification of the third detection unit 23 is 2 times, the solid angle required for extraction by the third mirror unit 13 is 1/100 of the solid angle of extraction from the light source 61. This equates to 1/10 in terms of NA.

The third portion L13 incident to the concave mirror 14 and reflected by the concave mirror 14 is detected by the third detection unit 23. In other words, the third detection unit 23 detects the third portion L13 reflected by the third mirror unit 13. For example, the third detection unit 23 includes a TDI sensor. The third detection unit 23 acquires a monitor image of an intensity distribution or the like of the generated light L0. The third detection unit 23 includes a plurality of image capturing elements arranged in a line-shape in one direction. In a similar manner to the main detection unit 73, image data in a line-shape captured by the plurality of image capturing elements arranged in a line-shape is referred to as one-dimensional image data or one frame. The third detection unit 23 acquires a plurality of pieces of one-dimensional image data by performing a scan in a direction orthogonal to the one direction. The one-dimensional image data acquired by the third detection unit 23 indicates an intensity distribution including a power variation and a brightness distribution of the generated light L0. For example, the image capturing element is a CCD (Charge Coupled Device). Note that the image capturing element is not limited to a CCD.

For example, the optical systems are arranged so that an image of the light-emitting point LP of the generated light L0 is formed in the third detection unit 23. Accordingly, the monitor unit 15 illuminates the third detection unit 23 by a critical illumination using the third portion L13 of the generated light L0. In addition, the monitor unit 15 acquires image data of the detected intensity distribution of the generated light L0. Therefore, an intensity distribution including a power variation and a brightness distribution can be detected with accuracy.

In this manner, the monitor unit 15 focuses the third portion L13 of the generated light L0 and detects the focused third portion L13 with the third detection unit 23. The third detection unit 23 outputs output information including information regarding the detected intensity distribution including a power variation and a brightness distribution of the generated light L0 to the image processing unit 30. The output information includes image data and the like detected by the third detection unit 23. The output information is outputted to the image processing unit 30 and processed into two-dimensional image data. In the image processing unit 30, the acquiring unit 31 acquires the output information of the third detection unit 23 and acquires the intensity distribution of the generated light L0 based on the acquired output information.

According to the present embodiment, since the monitor unit 15 acquires an intensity distribution including a power variation and a brightness distribution of the generated light L0, states of the light-emitting point LP and the illumination light L10 can be acquired with higher accuracy. Other configurations and advantageous effects are included in the descriptions of the first to third embodiments.

### Fifth Embodiment

Next, an optical apparatus according to a fifth embodiment will be described. The optical apparatus according to the present embodiment is an inspection apparatus and the object 50 includes the main detection unit 73. FIG. 16 is a configuration diagram illustrating an inspection apparatus 5 according to the fifth embodiment. In the embodiments described earlier, the object 50 is, for example, a photomask or the like arranged on the stage 52. Therefore, the first mirror unit 11 and the second mirror unit 12 are arranged on the optical path of the generated light L0 between the light-emitting point LP and the object 50 on the stage 52. On the other hand, in the present embodiment, since the object 50 constitutes the main detection unit 73, at least one of the first mirror unit 11 and the second mirror unit 12 may be arranged on the optical path of the generated light L0 between the light-emitting point LP and the main detection unit 73.

For example, as shown in FIG. 16, in the present embodiment, the first mirror unit 11 and the second mirror unit 12 may be arranged on the optical path of the generated light L0 between the convex mirror 72 and the main detection unit 73. An observation object 50a such as a photomask is arranged on the stage 52. In this manner, the inspection apparatus 5 according to the present embodiment includes the main detection unit 73 that detects light from the observation object 50a arranged on the optical path of the main portion LM of the generated light L0 and the processing unit 33 that processes an image of the observation object 50a based on output information of the main detection unit 73. In addition, the object 50 constitutes the main detection unit 73. The main detection unit 73 may be a detection unit that detects, for example, the illumination light L10 having been reflected by or transmitted through the observation object 50a that is a photomask or the like arranged on the stage 52.

According to the present embodiment, since the first mirror unit 11 and the second mirror unit 12 are capable of separating the first portion L11 and the second portion L12 from the generated light L0 including the illumination light L10 immediately before the illumination light L10 is incident to the main detection unit 73, a state of the illumination light L10 detected by the main detection unit 73 can be detected with greater detail. Other configurations and advantageous effects are included in the descriptions of the first to fourth embodiments.

Note that the configurations of the optical apparatuses 1 and 2 and the inspection apparatuses 3 to 5 described above can be applied to an exposure apparatus. For example, the illumination light L10 may include exposure light for exposing a wafer. In addition, the object 50 may include a wafer having a region that is activated based on light from a photomask arranged on an optical path of the exposure light. In such a case, at least one of the first mirror unit 11 and the second mirror unit 12 may be arranged on the optical path of the exposure light between the light-emitting point LP and the wafer.

In addition, the object 50 may include a photomask that forms a pattern on the wafer. In such a case, the first mirror unit 11 and the second mirror unit 12 are arranged on the optical path of the exposure light between the light-emitting point LP and the photomask.

While embodiments of the present disclosure have been described above, the present disclosure includes appropriate modifications that do not impair its purpose and advantages and, further, the present disclosure is not limited by the above embodiments. In addition, combinations of the respective configurations of the first to fifth embodiments are also within the scope of the technical concepts of the present disclosure. Furthermore, the following configurations also fall within the scope of embodiments.

### (Supplementary Note 1)

A control method of an optical apparatus that illuminates an object with illumination light,
the optical apparatus including:
a first mirror unit that reflects a first portion of generated light including the illumination light from a light-emitting point of the generated light;
a second mirror unit that reflects a second portion of the generated light;
an optical element that reflects the generated light;
a first detection unit that detects the first portion reflected by the first mirror unit;
a second detection unit that detects the second portion reflected by the second mirror unit; and
an image processing unit including an acquiring unit and a determining unit,
the generated light including the first portion, the second portion, and a main portion, in which
the control method of an optical apparatus comprises the steps of:
illuminating the object with the illumination light including at least a part of the main portion reflected by the optical element;
causing the acquiring unit to acquire first output information of the first detection unit and second output information of the second detection unit at a plurality of sampling time points; and
causing the determining unit to determine a state of the light-emitting point based on a change in the first output information and a change in the second output information.

### (Supplementary Note 2)

The control method of an optical apparatus according to supplementary note 1, in which
the first mirror unit separates the first portion from an optical path of the main portion, and
the second mirror unit separates the second portion from the optical path of the main portion.

### (Supplementary Note 3)

The control method of an optical apparatus according to supplementary note 1, in which
in the step of causing the determining unit to determine a state,
the determining unit is caused to determine, based on a change in the first output information of the first detection unit and a change in the second output information of the second detection unit between a predetermined sampling time point and a sampling time point after the predetermined sampling time point, a movement of the light-emitting point in an optical axis direction of the generated light and a movement of the light-emitting point in an orthogonal direction that is orthogonal to the optical axis direction.

### (Supplementary Note 4)

The control method of an optical apparatus according to supplementary note 1, in which
in the step of causing the determining unit to determine a state,
the determining unit is caused to determine, based on a change in the first output information of the first detection unit and a change in the second output information of the second detection unit between a predetermined sampling time point and a sampling time point after the predetermined sampling time point, a movement of the light-emitting point in an optical axis direction of the generated light and a change in emission intensity at the light-emitting point.

### (Supplementary Note 5)

The control method of an optical apparatus according to supplementary note 3, in which
in the step of causing the determining unit to determine a state,
the determining unit is caused to determine, based on a change in the first output information of the first detection unit and a change in the second output information of the second detection unit between a predetermined sampling time point and a sampling time point after the predetermined sampling time point, a change in emission intensity at the light-emitting point.

### (Supplementary Note 6)

The control method of an optical apparatus according to supplementary note 5, in which
in the step of causing the determining unit to determine a state,
the determining unit is caused to determine that the emission intensity at the light-emitting point has changed when at least one of a change in intensity of the light-emitting point based on the first output information and a change in intensity of the light-emitting point based on the second output information is detected and, at the same time, a movement of the light-emitting point based on the first output information and a movement of the light-emitting point based on the second output information are not detected.

### (Supplementary Note 7)

The control method of an optical apparatus according to supplementary note 4, in which
in the step of causing the acquiring unit to acquire first output information and second output information,
the acquiring unit is caused to acquire a first image by capturing the light-emitting point from the first output information, the first image having a transverse direction and a longitudinal direction that is orthogonal to the transverse direction, and acquire a second image by capturing the light-emitting point from the second output information, the second image having the transverse direction and the longitudinal direction.

### (Supplementary Note 8)

The control method of an optical apparatus according to supplementary note 7, in which
when the light-emitting point moves in the optical axis direction, the light-emitting point in the first image and the light-emitting point in the second image move so as to have components in mutually opposite directions in at least one of the transverse direction and the longitudinal direction, and
when the light-emitting point moves in the orthogonal direction, the light-emitting point in the first image and the light-emitting point in the second image move so as to have components in a same direction in at least one of the transverse direction and the longitudinal direction.

### (Supplementary Note 9)

The control method of an optical apparatus according to supplementary note 7, in which
in the step of causing the determining unit to determine a state,
the determining unit is caused to determine that the light-emitting point has moved in the optical axis direction when the light-emitting point in the first image and the light-emitting point in the second image move so as to have components in mutually opposite directions in at least one of the transverse direction and the longitudinal direction, and determine that the light-emitting point has moved in the orthogonal direction when the light-emitting point in the first image and the light-emitting point in the second image move so as to have components in a same direction in at least one of the transverse direction and the longitudinal direction.

### (Supplementary Note 10)

The control method of an optical apparatus according to supplementary note 1, in which
the first detection unit and the second detection unit are arranged at optically conjugate positions with respect to the object.

### (Supplementary Note 11)

The control method of an optical apparatus according to supplementary note 3, in which
the generated light further includes a third portion,
the optical apparatus further includes:
a third mirror unit that reflects the third portion; and
a third detection unit that detects the third portion reflected by the third mirror unit, and
the control method of an optical apparatus further comprises the step of:
causing the acquiring unit to acquire third output information of the third detection unit and acquire an intensity distribution of the generated light based on the acquired third output information.

### (Supplementary Note 12)

The control method of an optical apparatus according to supplementary note 11, in which
the third portion is closer to an optical axis of the main portion than the first portion and the second portion.

### (Supplementary Note 13)

The control method of an optical apparatus according to supplementary note 1, in which
the illumination light is a critical illumination.

### (Supplementary Note 14)

The control method of an optical apparatus according to supplementary note 1, in which
the optical apparatus includes a mirror that reflects the generated light generated at the light-emitting point, and
the first portion, the second portion, and the main portion are the generated light reflected by the mirror.

### (Supplementary Note 15)

The control method of an optical apparatus according to supplementary note 1, in which
the illumination light includes a wavelength of EUV.

### (Supplementary Note 16)

The control method of an optical apparatus according to supplementary note 1, in which
the first detection unit and the second detection unit detect light of wavelengths that differ from a wavelength of the illumination light.

### (Supplementary Note 17)

The control method of an optical apparatus according to supplementary note 1, in which
the first mirror unit and the second mirror unit are arranged at approximately same optical path positions on an optical axis of the main portion.

### (Supplementary Note 18)

The control method of an optical apparatus according to supplementary note 17, in which
the first mirror unit and the second mirror unit are arranged at opposite positions across an optical axis of the main portion.

### (Supplementary Note 19)

The control method of an optical apparatus according to supplementary note 1, in which
the optical apparatus further includes:
a fourth detection unit that detects the illumination light including the main portion reflected by the object; and
a processing unit that processes an image of the object based on fourth output information of the fourth detection unit.

### (Supplementary Note 20)

The control method of an optical apparatus according to supplementary note 18, in which
the object includes a photomask.

### (Supplementary Note 21)

The control method of an optical apparatus according to supplementary note 1, in which
the optical apparatus further includes:
a fourth detection unit that detects light from an observation object arranged on an optical path of the main portion; and
a processing unit that processes an image of the observation object based on fourth output information of the fourth detection unit, and
the object includes the fourth detection unit.

### (Supplementary Note 22)

The control method of an optical apparatus according to supplementary note 1, in which
the illumination light includes exposure light for exposing a wafer, and
the object includes a wafer having a region that is activated based on light from a photomask arranged on an optical path of the illumination light.

### (Supplementary Note 23)

The control method of an optical apparatus according to supplementary note 1, in which
the illumination light includes exposure light for exposing a wafer, and
the object includes a photomask that forms a pattern on the wafer.

A program can be stored and provided to a computer using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g. magneto-optical disks), CD-ROM (compact disc read only memory), CD-R (compact disc recordable), CD-R/W (compact disc rewritable), and semiconductor memories (such as mask ROM, PROM (programmable ROM), EPROM (erasable PROM), flash ROM, RAM (random access memory), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g. electric wires, and optical fibers) or a wireless communication line.

The first to fifth embodiments can be combined as desirable by one of ordinary skill in the art.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. An optical apparatus that illuminates an object with illumination light, the optical apparatus comprising:
a first mirror unit configured to reflect a first portion of generated light including the illumination light generated from a light-emitting point;
a second mirror unit configured to reflect a second portion of the generated light;
an optical element configured to reflect the generated light;
a first detection unit configured to detect the first portion reflected by the first mirror unit; and
a second detection unit configured to detect the second portion reflected by the second mirror unit, wherein
the generated light includes the first portion, the second portion, and a main portion, and
at least a part of the main portion reflected by the optical element is the illumination light that illuminates the object.

2. The optical apparatus according to claim 1, wherein
the first mirror unit is configured to separate the first portion from an optical path of the main portion, and
the second mirror unit is configured to separate the second portion from the optical path of the main portion.

3. The optical apparatus according to claim 1, further comprising:
an acquiring unit configured to acquire first output information of the first detection unit at a plurality of sampling time points and second output information of the second detection unit at the plurality of sampling time points; and
a determining unit configured to determine a state of the light-emitting point based on a change in the first output information and a change in the second output information.

4. The optical apparatus according to claim 3, wherein
the determining unit is configured to determine, based on a change in the first output information of the first detection unit and a change in the second output information of the second detection unit between a predetermined sampling time point and a sampling time point after the predetermined sampling time point, a movement of the light-emitting point in an optical axis direction of the generated light and a movement of the light-emitting point in an orthogonal direction that is orthogonal to the optical axis direction.

5. The optical apparatus according to claim 3, wherein
the determining unit is configured to determine, based on a change in the first output information of the first detection unit and a change in the second output information of the second detection unit between a predetermined sampling time point and a sampling time point after the predetermined sampling time point, a change in emission intensity at the light-emitting point.

6. The optical apparatus according to claim 5, wherein
the determining unit is configured to determine that the emission intensity at the light-emitting point has changed when at least one of a change in intensity of the light-emitting point based on the first output information and a change in intensity of the light-emitting point based on the second output information is detected and, at the same time, a movement of the light-emitting point based on the first output information and a movement of the light-emitting point based on the second output information are not detected.

7. The optical apparatus according to claim 4, wherein
the acquiring unit is configured to acquire a first image by capturing the light-emitting point from the first output information, the first image having a transverse direction and a longitudinal direction that is orthogonal to the transverse direction, and acquire a second image by capturing the light-emitting point from the second output information, the second image having the transverse direction and the longitudinal direction.

8. The optical apparatus according to claim 7, wherein
when the light-emitting point moves in the optical axis direction, the light-emitting point in the first image and the light-emitting point in the second image move so as to have components in mutually opposite directions in at least one of the transverse direction and the longitudinal direction, and
when the light-emitting point moves in the orthogonal direction, the light-emitting point in the first image and the light-emitting point in the second image move so as to have components in a same direction in at least one of the transverse direction and the longitudinal direction.

9. The optical apparatus according to claim 7, wherein
the determining unit is configured to determine that the light-emitting point has moved in the optical axis direction when the light-emitting point in the first image and the light-emitting point in the second image move so as to have components in mutually opposite directions in at least one of the transverse direction and the longitudinal direction, and determine that the light-emitting point has moved in the orthogonal direction when the light-emitting point in the first image and the light-emitting point in the second image move so as to have components in a same direction in at least one of the transverse direction and the longitudinal direction.

10. The optical apparatus according to claim 1, wherein
the first detection unit and the second detection unit are arranged at optically conjugate positions with respect to the object.

11. The optical apparatus according to claim 3, wherein
the generated light further includes a third portion,
the optical apparatus further comprises:
a third mirror unit configured to reflect the third portion; and
a third detection unit configured to detect the third portion reflected by the third mirror unit, and
the acquiring unit is configured to acquire third output information of the third detection unit and acquire an intensity distribution of the generated light based on the acquired third output information.

12. The optical apparatus according to claim 11, wherein
the third portion is closer to an optical axis of the main portion than the first portion and the second portion.

13. The optical apparatus according to claim 1, wherein
the illumination light illuminates the object with critical illumination.

14. The optical apparatus according to claim 1, comprising:
a mirror configured to reflect the generated light occurring at the light-emitting point, and
the first portion, the second portion, and the main portion are contained in the generated light reflected by the mirror.

15. The optical apparatus according to claim 1, wherein
the illumination light includes a wavelength of EUV.

16. The optical apparatus according to claim 1, wherein
the first detection unit and the second detection unit are configured to detect light of wavelengths that differ from a wavelength of the illumination light.

17. The optical apparatus according to claim 1, wherein
the first mirror unit and the second mirror unit are arranged at approximately same optical path positions on an optical axis of the main portion.

18. The optical apparatus according to claim 17, wherein
the first mirror unit and the second mirror unit are arranged at opposite positions across an optical axis of the main portion.

19. The optical apparatus according to claim 1, further comprising:
a fourth detection unit configured to detect the illumination light including the main portion reflected by the object; and
a processing unit configured to process an image of the object based on fourth output information of the fourth detection unit.

20. The optical apparatus according to claim 18, wherein
the object includes a photomask.

21. The optical apparatus according to claim 1, further comprising:
a fourth detection unit configured to detect light from an observation object arranged on an optical path of the main portion; and
a processing unit configured to process an image of the observation object based on fourth output information of the fourth detection unit, wherein
the object includes the fourth detection unit.

22. The optical apparatus according to claim 1, wherein
the illumination light includes exposure light to expose a wafer, and
the object includes a wafer having a region that is activated based on light from a photomask arranged on an optical path of the exposure light.

23. The optical apparatus according to claim 1, wherein
the illumination light includes exposure light to expose a wafer, and
the object includes a photomask configured to form a pattern on the wafer.

24. A control method of an optical apparatus that illuminates an object with illumination light,
the optical apparatus including:
a first mirror unit that reflects a first portion of generated light including the illumination light from a light-emitting point of the generated light;
a second mirror unit that reflects a second portion of the generated light;
an optical element that reflects the generated light;
a first detection unit that detects the first portion reflected by the first mirror unit;
a second detection unit that detects the second portion reflected by the second mirror unit;
an acquiring unit;
and a determining unit,
the generated light including the first portion, the second portion, and a main portion, wherein
the control method of an optical apparatus comprises the steps of:
illuminating the object with the illumination light including at least a part of the main portion reflected by the optical element;
causing the acquiring unit to acquire first output information of the first detection unit and second output information of the second detection unit at a plurality of sampling time points; and
causing the determining unit to determine a state of the light-emitting point based on a change in the first output information and a change in the second output information.

25. The optical apparatus according to claim 2, further comprising:
an acquiring unit configured to acquire first output information of the first detection unit at a plurality of sampling time points and second output information of the second detection unit at the plurality of sampling time points; and
a determining unit configured to determine a state of the light-emitting point based on a change in the first output information and a change in the second output information.

26. The optical apparatus according to claim 25, wherein
the determining unit is configured to determine, based on a change in the first output information of the first detection unit and a change in the second output information of the second detection unit between a predetermined sampling time point and a sampling time point after the predetermined sampling time point, a movement of the light-emitting point in an optical axis direction of the generated light and a movement of the light-emitting point in an orthogonal direction that is orthogonal to the optical axis direction.

27. The optical apparatus according to claim 25, wherein
the determining unit is configured to determine, based on a change in the first output information of the first detection unit and a change in the second output information of the second detection unit between a predetermined sampling time point and a sampling time point after the predetermined sampling time point, a change in emission intensity at the light-emitting point.

28. The optical apparatus according to claim 27, wherein
the determining unit is configured to determine that the emission intensity at the light-emitting point has changed when at least one of a change in intensity of the light-emitting point based on the first output information and a change in intensity of the light-emitting point based on the second output information is detected and, at the same time, a movement of the light-emitting point based on the first output information and a movement of the light-emitting point based on the second output information are not detected.

29. The optical apparatus according to claim 26, wherein
the acquiring unit is configured to acquire a first image by capturing the light-emitting point from the first output information, the first image having a transverse direction and a longitudinal direction that is orthogonal to the transverse direction, and acquire a second image by capturing the light-emitting point from the second output information, the second image having the transverse direction and the longitudinal direction.

30. The optical apparatus according to claim 2, wherein
the first detection unit and the second detection unit are arranged at optically conjugate positions with respect to the object.

31. The optical apparatus according to claim 2, comprising:
a mirror configured to reflect the generated light occurring at the light-emitting point, and
the first portion, the second portion, and the main portion are contained in the generated light reflected by the mirror.
